(19) United States
(12) Patent Application Publication
(10) Pub. No.: US 2008/0169535 A1
(43) Pub. Date: Jul. 17, 2008

(54) SUB-LITHOGRAPHIC FACETING FOR MOSFET PERFORMANCE ENHANCEMENT

(75) Inventors: Shahid A. Butt, Ossining, NY (US); Thomas W. Dyer, Pleasant Valley, NY (US); Oh-Jung Kwon, Hopewell Junction, NY (US); Jack A. Mandelman, Flat Rock, NC (US); Haining S. Yang, Wappingers Falls, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/622,588

(22) Filed: Jan. 12, 2007

(51) Int. Cl. H01L 29/06; H01L 21/311

(52) U.S. Cl. 257/622; 438/701; 257/E29.005; 257/E21.249

(57) ABSTRACT

The present invention provides structures and methods for providing multiple parallel V-shaped faceted grooves with sub-lithographic widths on a semiconductor substrate for enhanced performance MOSFETs. A self-aligning self-assembling material is used to pattern multiple parallel sub-lithographic lines. By employing an anisotropic etch that produces crystallographic facets on a semiconductor surface, multiple adjoining parallel V-shaped grooves with sub-lithographic groove widths are formed. While providing enhanced mobility for the MOSFET, the width of the MOSFET is not limited by the depth of focus in subsequent lithographic steps or the thickness of semiconductor layer above a BOX layer due to the sub-lithographic widths of the V-shaped grooves and the consequent reduction in the variation of the vertical profile. Also, the MOSFET has a well defined threshold voltage due to the narrow widths of each facet.

### FIELD OF THE INVENTION

The present invention relates to semiconductor devices, and particularly, to complementary metal oxide semiconductor (CMOS) transistors having facets with sub-lithographic widths.

### BACKGROUND OF THE INVENTION

Performance of semiconductor field effect transistors depends on the crystallographic surface orientation on which the channel of the transistor is built through the mobility of minority channel carriers. For example, the electron mobility in silicon is the highest for the {100} surface orientations and the lowest for the {110} surface orientations, while the hole mobility is the highest for the {110} surface orientations and the lowest for the {100} surface orientations within silicon single crystal.

Use of different crystallographic planes for PFET and NFET devices to enhance the performance of the overall circuit has been known in the prior art. This class of technology, called “hybrid orientation technology (HOT)” in the industry, provides methods of manufacturing PFET devices and NFET devices on different crystallographic planes on the same substrate.

In one approach, bonding of wafers followed by epitaxial growth of semiconductor material is used to provide semiconductor surfaces with different surface orientations. One such example, U.S. Pat. No. 7,102,166 B1 to Bryant et al., discloses a method in which two wafers with different wafer surface orientations are bonded together to provide a structure having different crystallographic planes on the surface. The bonding step is followed by a silicon epitaxy to create a flat wafer surface with two different surface orientations. A second such example, U.S. Patent Application Publication No. US2006/0194421 A1 by Ieong et al., discloses a similar approach in which a pattern on the bonded wafer is etched down to the bottom of the buried oxide layer and then a semiconductor material is regrown in a selective epitaxy to form a semiconductor surface coplanar with the semiconductor surface with the SOI portion and having the same surface orientation as the underlying substrate. General disadvantages of this type of approach include defect generation during the epitaxial growth of the semiconductor, a high level of defect density near the boundaries, and the complexity and cost of the processes.

A different approach utilizing facets with different crystallographic orientations than the original surface of a semiconductor substrate is known in the prior art. Typically, on a semiconductor substrate provided with an original semiconductor surface, a portion of the semiconductor surface is patterned and exposed while the rest of the semiconductor surface is covered with a masking layer. A V-shaped groove is formed by subjecting the exposed portion of the semiconductor surface to an anisotropic etch process having different etch rates along different crystallographic planes of the semiconductor material. In an example, Weber et al., “A Novel Locally Engineered (111) V-channel MOSFET Architecture with Improved Drivability Characteristics for Low-Standby power (LSTP) CMOS Applications,” 2005 Symposium on VLSI, 2005, pp. 156-157, discloses a transistor structure in which a channel is formed within a V-shaped groove. The current flows within the plane of the V-shape groove following the path in the shape of the letter, V, including an inflection in the direction of the current in the middle of the channel.

Formation of crystallographic facets, such as may be formed by V-shaped grooves, is subject to some limitations that adversely affect the performance of a MOSFET. Specifically, the upper limit on the width of the V-shaped grooved is placed on the layout of the devices with a V-shaped groove by the maximum field of depth that a lithographic tool can handle since a very wide V-shaped groove creates a very large variation in the vertical profile of gate lines that needs to be patterned lithographically. Also, in the cases involving an SOI substrate, a V-shaped groove wider than about twice the thickness of the semiconductor material above the buried oxide (BOX) layer becomes impossible since an attempt at generation of a V-shaped groove would expose the BOX layer before a wide V-shaped groove can be formed due to the limited thickness of the semiconductor layer above the BOX layer. Limiting the width of the devices built on V-shaped grooves below a limit placed either due to the field of depth requirement of subsequent lithography steps or due to a limited thickness of the top semiconductor layer of an SOI substrate severely limits the layout of the MOSFET design utilizing V-shaped grooves. While a MOSFET with an effectively wider device width may be built by connecting multiple MOSFETs built on a V-shaped groove, such a layout requires an STI region between adjacent V-shaped grooves, thereby requiring a large semiconductor area.

Therefore, there exists a need for structures and methods for forming crystallographic facets on a wide semiconductor area. Also, there exists a need to limit the variation of vertical profiles of V-shaped grooves.

Furthermore, due to the formation of corners on a gated surface of a V-shaped groove, the electrical filed at the corners of the V-shaped groove of a semiconductor is higher than that on a flat semiconductor surface. This results in dual threshold voltages from a MOSFET built on a V-shaped groove, wherein a lower threshold voltage corresponds to the edge portion of the V-shaped groove and a higher threshold voltage corresponds to the portion of the V-shaped groove away from the edges. This deteriorates the I_on to I_off ratio of the device. The difference in the threshold voltage is ultimately due to the finite size of the width of the crystallographic facets. A narrower crystallographic facet reduces this effect.

Therefore, there also exists a need to reduce the width of the crystallographic facets so that the effect of different threshold voltage from different parts of the V-shaped groove is minimized.

### SUMMARY OF THE INVENTION

To address the needs described above, the present invention utilizes sub-lithographic self-aligned self-assembly of resist material combined with anisotropic etching of a semiconductor material to create multiple parallel shallow V-shaped grooves with facets having different crystallographic orientation on a semiconductor substrate.

Specifically, the present invention provides multiple V-shaped grooves instead of one, as was enabled by the prior art to address the need to form crystallographic facets on a wide semiconductor area.

The present invention limits the vertical variation of profiles of V-shaped grooves to less than about ⅓ of the minimum lithographic dimension, “F,” through the use of sub-lithographic self-assembly of resist material to address the need for facets with limited variation in the vertical profile of the V-shaped structure.

The present invention increases I_on to I_off ratio by making the width of each of the V-shaped grooves narrower than the minimum lithographic dimension, “F.”

The present invention utilizes conventional silicon substrates (bulk or SOI), sub-lithographic patterning, and crystallographic etching to achieve multiple adjoined parallel V-shaped channels of sub-lithographic widths on the same wafer. After STI is formed, conventional lithography is combined with sub-lithographic molecular self-assembly performed on selected devices. For the selected devices, an anisotropic crystallographic etch forms multiple adjoined sub-lithographic channels with different surface orientation than the substrate orientation. The present invention is suitable for any device width without significant complications for gate stack patterning or circuit density. Typically, only one of the 2 complementary device types (e.g. PFETs) is etched in an anisotropic etch while the other device type (e.g. NFETs) is masked from the anisotropic etch.

According to the present invention, a semiconductor substrate with a substrate orientation is divided into two areas, a first area wherein the substrate orientation is an optimal orientation for the first type of CMOS devices to be built thereupon and a second area wherein the substrate orientation is an optimal orientation for the second type of CMOS devices to be built thereupon. For example, for a (100) silicon substrate, the first area is an NFET area and the second area is a PFET area. For a (110) silicon substrate, the first area is a PFET area and the second area is an NFET area. Also, while {110} orientations are preferred for a PFET area on silicon, other crystallographic orientations such as {111}, {211}, {221}, and {311} may be utilized according to the present invention. Similarly, while {100} orientations are preferred for an NFET area on silicon, other crystallographic orientations such as {111}, {211}, {221}, and {311} may be utilized according to the present invention. The present invention is described for a (100) silicon substrate with the first area being an NFET area and the second area being the PFET area with the understanding that the modifications with different crystallographic orientations and different substrate material is within the knowledge of one of ordinary skill in the art.

According to the present invention, a stack of a pad oxide layer and a nitride layer is deposited on a (100) silicon substrate and patterned with shallow trench isolation (STI). A first photoresist is applied and patterned such that the silicon area for the PFETs, or the PFET area, is exposed after exposure and development of the first photoresist. The first photoresist is patterned such that the length of two long parallel edges of an opening in the first photoresist is greater than the width of the opening. Preferably, the opening is a parallelepiped with the two long parallel edges longer than the distance between them. Most preferably, the parallelepiped is a rectangle. A self-aligning self-assembling lithographic material is then applied to the silicon substrate. The self-aligning self-assembling lithographic material is self-aligned to the pre-defined lithographic opening in the first photoresist. Preferably, the length to width ratio of the rectangular opening in the first photoresist is selected to enable substantially long parallel alignment of the self-aligning self-assembling lithographic material. Thus, the self-aligned self-assembling material is aligned to the existing pattern of the first photoresist to define long parallel lines of sub-lithographic widths.

The stack of pad oxide and pad nitride in the area between the long parallel lines of self-aligned self-assembling material is then exposed to an etch process. The exposed pad nitride between the long parallel lines of sub-lithographic widths formed by the self-aligned self-assembling material is first etched preferably by reactive ion etch (RIE). The pad oxide below the etched portion of the pad nitride is then etched either by a RIE or by a wet etch. A first portion of the silicon substrate located between the long parallel lines of self-aligned self-assembling material is then exposed. The remaining pad oxide and pad nitride under the long parallel lines of self-aligned self-assembling material of sub-lithographic widths form multiple parallel stacks of sub-lithographic width, which is also formed in long parallel lines like the self-aligned self-assembling material above them.

Preferably, the first photoresist and the self-aligned self-assembling material are then removed. At this point, the silicon area for the NFETs, or the NFET area, is covered with a contiguous stack of pad oxide and pad nitride. Also, multiple parallel stacks pad oxide and pad nitride in the form of long parallel lines of sub-lithographic widths cover the PFET area. A first anisotropic etch with different etch rates along different crystallographic orientations of the silicon substrate is then performed. The exposed portion, or the first portion, of the PFET area between the parallel lines formed by the stack of remaining pad oxide and pad nitride is etched to form V-shaped grooves.

The anisotropic etch forms multiple parallel V-shaped grooves between the parallel lines of the self-aligned self-assembling material. The multiple parallel V-shaped grooves are not joined to each other at this point, that is, they are non-adjoining multiple parallel V-shaped grooves. Preferably, the outer edges of the crystallographic facets are close to the edges of the multiple parallel stacks of the remaining pad oxide and pad nitride. Each of the multiple non-adjoining parallel V-shaped grooves is separated by a flat portion of the semiconductor surface between the neighboring V-shaped grooves. The flat portions of the semiconductor surface are covered by the multiple parallel stacks of the remaining pad oxide and pad nitride at this point.

According to the first embodiment of the present invention, a second photoresist is then applied and patterned such that the NFET area is covered with the second photoresist. The multiple parallel stacks of the remaining pad oxide and pad nitride of sub-lithographic widths are then removed preferably by a wet etch. The multiple non-adjoining parallel V-shaped grooves and the flat portions of semiconductor surface between neighboring pairs of the V-shaped grooves are then etched further to widen the V-shaped grooves. Since the etch rate of the surface for the flat portions is lower than the etch rate for the facets on the existing V-shaped grooves, the V-shaped grooves expand during the second anisotropic etch until the neighboring parallel outer edges of the V-shaped meet and each of the V-shaped grooves adjoins the neighboring V-shaped grooves. During the process of the anisotropic etching, the size of each of the crystallographic facets of the V-shaped grooves grows until the outer edges of V-shaped grooves meet other outer edges from neighboring V-shaped grooves. Since each V-shaped groove has two trapezoid facets adjoined by a ridge an the present invention enables multiple parallel V-shaped grooves wherein the outer edges are adjoined between neighboring V-shaped grooves, the present invention enables at least four trapezoid crystallographic facets joined either by ridges or by outer edges of V-shaped grooves.

According to the first embodiment of the present invention, the pitch of the adjoining parallel V-shaped grooves is equal to the sub-lithographic pitch of the self-aligned self-assembling lithographic material.

According the second embodiment of the present invention, after the anisotropic etch forms multiple non-adjoining parallel V-shaped grooves between the parallel lines of the self-aligned self-assembling material, a sacrificial oxide is formed on the multiple non-adjoining parallel V-shaped grooves with crystallographic facets by growth or deposition. Next, the volume above the sacrificial oxide between the multiple stacks of remaining pad oxide and pad nitride of sub-lithographic widths is filled with a second photoresist. Preferably, the filling of the volume between the stacks of sub-lithographic widths is achieved by applying the second photoresist and recessing it such that no resist remains on the wafer except between the stacks of sub-lithographic widths. Preferably, the NFET area of the silicon substrate is masked with a third photoresist to protect the pad oxide and pad nitride in the NFET area.

The multiple stacks of the remaining pad oxide and pad nitride of sub-lithographic widths are then removed to expose the flat portions of semiconductor surface between neighboring pairs of the V-shaped grooves. Preferably, the second and the third resist are also removed at this point leaving only sacrificial oxide over the non-adjoining parallel V-shaped grooves. A second anisotropic etch is performed to form more V-shaped grooves between the non-adjoining parallel V-shaped grooves covered with the sacrificial oxide. The second anisotropic etch has different etch rates along different crystallographic orientations of the semiconductor substrate like the first anisotropic etch. One V-shaped groove is formed in each of the flat portions of semiconductor surface between neighboring pairs of the V-shaped grooves. Thereafter, the sacrificial oxide is removed.

According to the second embodiment of the present invention, the pitch of the adjoining parallel V-shaped grooves is equal to one half of the sub-lithographic pitch of the self-aligned self-assembling lithographic material.

According to both embodiments, after the formation of the multiple parallel adjoining V-shaped grooves are completed, the pad oxide and pad nitride in the NFET area are removed. A gate dielectric is formed on the entire exposed silicon surface in the PFET and NFET area. Next, a gate conductor stack is deposited and patterned to form gate electrodes.

The resulting structure, according to both embodiments comprises a plurality of parallel adjoining V-shaped grooves with crystallographic facets within the (100) substrate. Each of the plurality of V-shaped grooves has two parallel outside edges that run parallel to the ridge near the middle of each groove. One aspect of the present invention is that each of the V-shaped grooves has at least one edge that meets another edge of a neighboring V-shaped groove. Therefore, the neighboring V-shaped grooves are adjoined.

Another aspect of the present invention is that the self-aligned self-assembling material forms multiple parallel lines of sub-lithographic widths. The benefits of this feature include the increase in the channel area by a factor of the inverse of the cosine of the angle of the facets to the original flat surface of the substrate, the increased minority carrier mobility achieved by the use of optimal crystallographic facets for the formation of the channel, and the minimized variation in the height of the semiconductor surfaces upon which MOSFET devices are built.

According to the present invention, the current flows along the pair of parallel edges and perpendicular to the cross-section that contains the multiple adjoining V-shaped profiles of the surfaces and of the channel. The physical channel is formed of the multiple adjoining V-shaped grooves, each with a ridge in the middle. The cross-sectional area of the channel within each of the V-shaped grooves perpendicular to the direction of the current has V-shaped profile.

Furthermore, each of the plurality of parallel adjoining V-shaped grooves with crystallographic facets has a width less than a lithographic minimum dimension. This is enabled due to the use of self-aligned self-assembling material that forms a pattern of lines of sub-lithographic width within the pre-patterned first resist. The minimum lithographic dimension, “F,” is the minimum width that can be printed directly on the resist using available lithographic tools. Since such a dimension depends on the capability of each lithographic tool used for creating such a pattern, the minimum lithographic dimension changes from tool to tool and from generation to generation. However, it is commonly accepted that the minimum lithographic dimension is the smallest feature size that can be imaged by the lithographic process in each generation of lithographic technology. Typically, with 248 nm lithography tools, this dimension is about 93 nm. With 193 nm technology tools, this dimension is about 65 nm. Since the minimum lithographic dimension is used for the printing of the gate pattern, the minimum dimension in the gate pattern as it appears on the developed photoresist tends to coincide with the lithographic minimum dimension.

Both embodiments enable PFETs built on {110} facets formed on the V-shaped grooves and NFETs built on surfaces with the substrate orientation of (100). This enables the maximum mobility for both the PFETs and the NFETs

A mirror image implementation of the present invention wherein the substrate is a (110) substrate is with the knowledge of one of ordinary skill in the art. In this case, the PFET area is masked with the first and third photoresist. The NFETs are built on {100} facets that are formed on the V-shaped grooves and PFETs are built on surfaces with the substrate orientation of (110). Also, the use of crystallographic facets with surface orientations of less-than-maximal carrier mobility is feasible. Some of such surfaces include {100} orientations, {110} orientations, {111} orientations, {211} orientations, {221} orientations, and {311} orientations.

Unlike the prior art, the present invention can be practiced on a silicon-on-insulator (SOI) substrate without being limited for the device width. This is because the V-shaped grooves according to the prior art produce height variations in the silicon surface of about one half of the width of the patterned semiconductor area that is exposed to an anisotropic etching. In ultra-thin SOI (UTSOI), wherein the thickness of the semiconductor layer above the buried oxide (BOX) layer is only about 50 nm, the thickness of the semiconductor layer limits the height variations in the vertical profile of the semiconductor area and thus, the width of a MOSFET built on a V-shaped groove is limited by the thickness of the semiconductor layer above the BOX according to the prior art. The present invention provides a solution by eliminating the limit on the width of the semiconductor area since multiple V-shaped grooves with less variations in the vertical height is formed instead. The variation in the vertical height is approximately one half of the pitch of the multiple adjoining V-shaped vertical grooves. Since the pitch of the V-shaped vertical grooves is less than the minimum lithographic dimension and there is at least one line and two spaces within one minimum lithographic dimension, the variation in the vertical profile is less than about one sixth of the minimum lithographic dimension.

Also, this invention can be combined with other techniques for altering the lattice parameters of the semiconductor substrate to enhance the transistor performance. For example, in addition to the single crystalline silicon, the silicon substrate may also contain an epitaxially disposed material on the single crystalline silicon substrate that is selected from the group consisting of: intrinsic silicon, intrinsic silicon germanium alloy, intrinsic silicon carbon alloy, intrinsic silicon germanium carbon alloy, P-doped silicon, P-doped silicon germanium alloy, P-doped silicon carbon alloy, P-doped silicon germanium carbon alloy, N-doped silicon, N-doped silicon germanium alloy, N-doped silicon carbon alloy, and N-doped silicon germanium carbon alloy.

Furthermore, given suitable chemicals to effect preferential etching as will be described below, the present invention may also be utilized on a III-V compound semiconductor substrate as well as a II-VI compound semiconductor substrate.

The present invention can also be practiced with the self-alignment of the V-shaped grooves to the STI. This is because the STI can serve as a natural limit for the formation of one of the two parallel edges for the V-shaped grooved formed adjacent to it. Even if the size of the facet that is adjacent to the STI is different from the size of the facets not adjoining the STI, the performance of the MOSFET formed on the multiple parallel V-shaped grooves is not affected significantly. However, the mask used for the patterning of the first photoresist may be advantageously allowed to have less stringent requirement for alignment, for example, by requiring a mid-ultraviolet (MUV) mask instead of a deep-ultraviolet (DUV) mask.

### BRIEF DESCRIPTION OF THE DRAWINGS

FIG. 1 is a graph of electron and hole mobility on (100), (110), and (111) surfaces according to the prior art.

FIG. 2 is a prior art SEM picture of a lithographically patterned 0.28 micron width space formed with a photoresist.

FIG. 3 is a prior art SEM picture of a self-aligned self-assembling material that was formed within a lithographically patterned 0.28 micron width space like one shown in FIG. 2.

FIG. 4A is a schematic top-down view of an exemplary implementation of the current invention.

FIG. 4B is a schematic cross-sectional view of the exemplary implementation of the current invention along the direction of B-B′ in FIG. 4A.

FIG. 5A is a schematic cross-sectional view of a prior art MOSFET with a V-shaped channel showing an area of high threshold voltage (Vt), A, and an area of low Vt, B.

FIG. 5B is a graph of the drain current as a function of the gate voltage of a prior art device shown in FIG. 5A.

FIG. 6A is a schematic cross-sectional view of a MOSFET with a parallel adjoined V-shaped channel with widths of sub-lithographic dimensions with the same Vt area, C according to the present invention

FIGS. 7A-15A are schematic top-down views of a MOSFET device according to the first embodiment of the present invention.

FIGS. 7B-15B are schematic cross-sectional views of the MOSFET device according to the first embodiment of the present invention along the direction of B-B′.

FIGS. 16A-25A are schematic top-down views of a MOSFET device according to the second embodiment of the present invention.

FIG. 25B is a schematic cross-sectional view of the MOSFET device according to the second embodiment of the present invention along the direction of B-B′.

### DETAILED DESCRIPTION OF THE INVENTION

Before describing the present invention in detail, a discussion on the prior art on surface orientation engineering on semiconductor material and self-aligned self-assembling material is provided. The discussion on the prior art is made herein to clearly illustrate the fundamental difference between the prior art and the present invention.

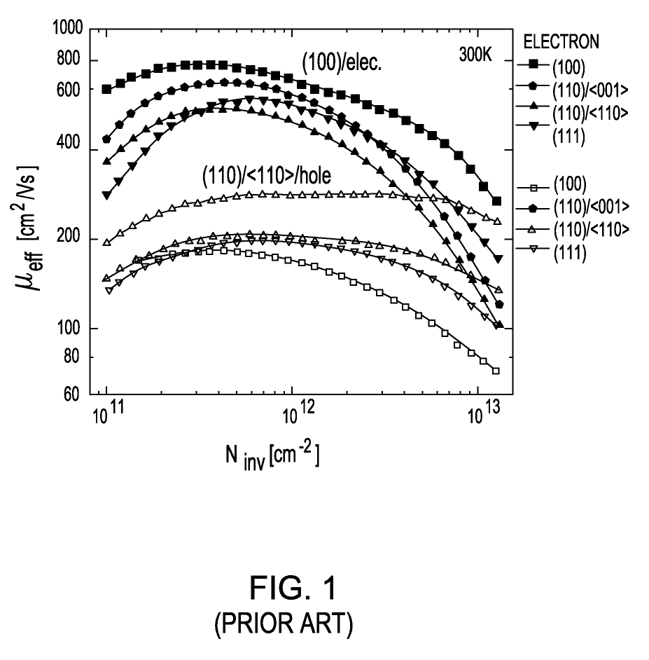

FIG. 1 is a graph of electron and hole mobility on (100), (110), and (111) surfaces from Irie et al., “In-Plane Mobility anisotropy and Universality Under Uniaxial Strains in n- and p-MOS Inversion Layers on (100), (110), and (111) Si,” IEDM Tech. Dig., 2004, pp. 225-228. Electron mobility on (100) and hole mobility on (110)/<110> give larger mobility than the others, respectively. This graph illustrates the principles of hybrid orientation technology (HOT) wherein multiple crystallographic facets are used to enhance the minority carrier mobility to enhance the performance of MOSFETs.

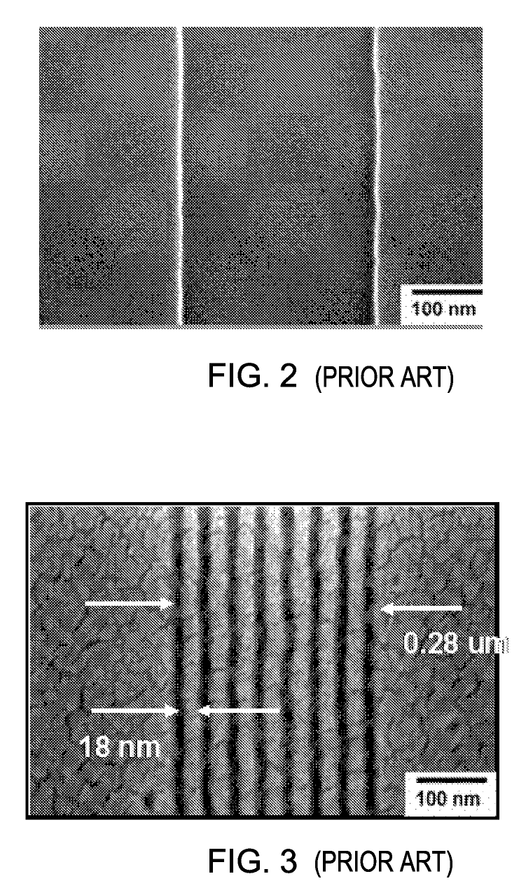

FIG. 2 shows an SEM picture of a 0.28 micron wide space formed with a conventional resist utilizing conventional lithography. To utilize self-aligned self-assembling material, a preexisting pattern of material is necessary so that the molecules of the self-assembling material also recognizes the geometry of the surrounding area and “align” to the features of the preexisting geometry in self-alignment. FIG. 3 shows a picture of a prior art SEM wherein the self-aligned self-assembling material is applied to and self-aligned to a preexisting 0.28 micron space structure. The pitch of the parallel lines formed with the self-aligned self-assembling material is 40 nm and is less than the minimum dimension that can be currently printed with conventional lithography without self-aligned self-assembling material.

References are made herein to the prior art publications that show methods of forming patterns of sub-lithographic width lines on a semiconductor substrate. These references include C. T. Black and R. Ruiz, “Self Assembly in Semiconductor Microelectronics: Self-Aligned Sub-Lithographic Patterning Using Diblock Copolymer Thin Films,” Proc. SPIE 6153, 615302 (2006); C. T. Black, “Self-Aligned, Self Assembly of Multi-Nanowire Silicon Field Effect Transistors,” Applied Physics Letters, 87, 163116 (2005); and C. T. Black, “Integration of Self Assembly for Microelectronics,” Proceedings of the IEEE Custom Integrated Circuits Conference, (2005). These reference collectively demonstrate the feasibility of the formation of patterns with sub-lithographic parallel lines.

According to this patterning method, the alignment capabilities of optical lithography are combined with the intrinsic nanometer-scale dimensions of self-aligning self-assembling material. In one example, the self-aligning self-assembling material is a copolymer wherein topography is used to direct the assembly of cylindrical copolymer domains so as to subdivide larger patterns defined using optical lithography, in the process precisely registering the location of each 20 nm polymer domain to the lithographic pattern.

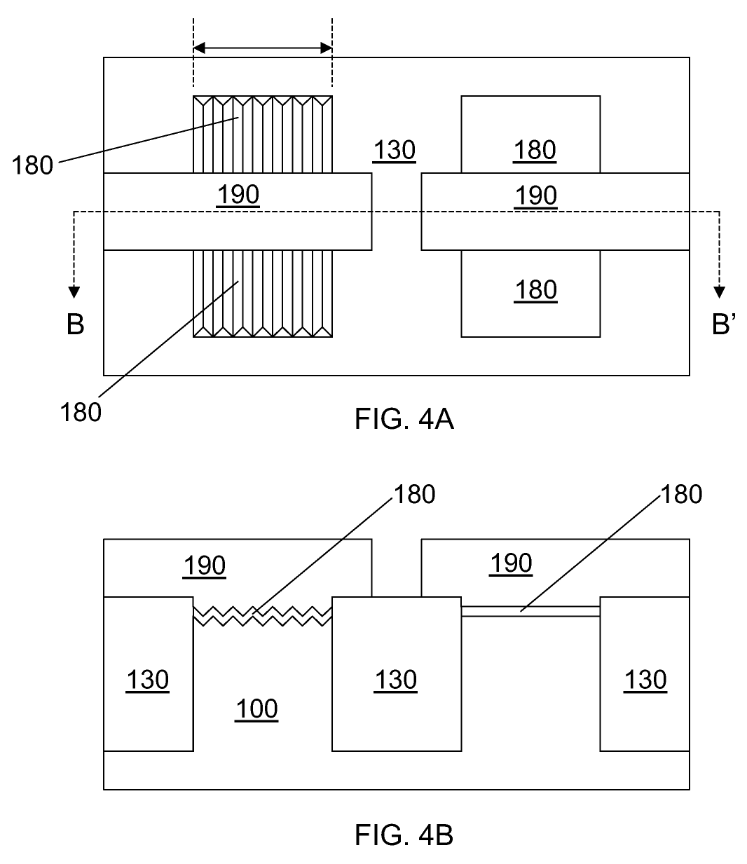

FIGS. 4A-4B are schematic views of a first MOSFET device with multiple parallel adjoining V-shaped grooves along with a second MOSFET built on a flat channel. STI 130 is formed on a (100) silicon substrate 100. A PFET is built on the left side of the figures and utilizing multiple parallel adjoining V-shaped grooves and an NFET is built on the right side of the figures using conventional methods. The gate dielectric 180 and the gate lines 190 are also shown. Preferably, the width of the gate lines 190 has the minimum lithographic dimension, “F” to maximize the performance of these transistors. While the total width, W, of the active area cannot be smaller than the minimum lithographic dimension, “F’, the width of individual V-shaped grooves are smaller than “F.” Furthermore, the width of each facet and the overall height variation in the vertical profile of the multiple parallel adjoining V-shaped grooves is much less than “F.”

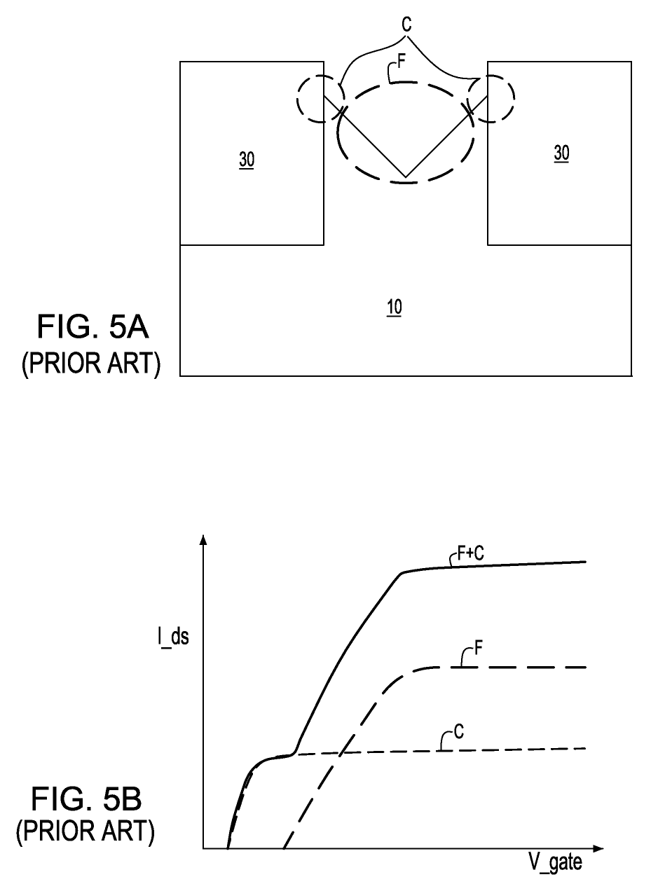

The advantageous electrical properties of the narrow width of individual facets of the multiple parallel adjoining V-shaped grooves is illustrated by comparing it with a prior art structure in FIG. 5A. FIG. 5A shows a cross-section of a MOSFET with a V-shaped channel according to the prior art. A single V-shaped channel is formed on a silicon substrate 10 and is surrounded by STI 30. Typically, faceting of the channel also results in the formation of corners on the gated surface which are convex with respect to the overlying gate line. Because of their geometry (curvature) relative to the gate line, the electric field at surface corners “C” in FIG. 5A is higher than that on the flat potion “F” of the crystallographic facets. This situation occurs when the width of individual facets is relatively wide, as with surfaces facets by standard lithographic processes. Due to the enhancement of the electric field at surface corners B on faceted surfaces, the high electric field regions are electrically distinct from the normal filed regions in the flat portion “F”. This occurs because the separation between adjacent corners is large relative to the gate dielectric thickness.

The resulting electrical characteristics of the prior art MOSFET in FIG. 5A is shown in FIG. 5B. The current contribution from the surface corners “C” in FIG. 5A is also labeled “C” in FIG. 5B. The current contribution from the flat portion “F” in FIG. 5A is also labeled “F” in FIG. 5B. The total channel current is labeled “F+C” in FIG. 5B and is the sum of the current contribution from the surface corners “C” and the current contribution from the flat portion “F.” The high-field regions (hot spots) in the surface corners “C” in FIG. 5A are electrically distinct and contribute to a large off-current leakage. Although the corners conduct with a sub-Vt slope which is superior to that obtained from a planar surface in the flat portion “F” in FIG. 5A, the surface corners “C” in FIG. 5A contribute much smaller on-current. Most of the on-current comes from the flat portion “F” in FIG. 5A, which has a larger effective gated area than the sum of the corners. Therefore, the presence of the surface corners serves only to degrade the Ion/Ioff ratio.

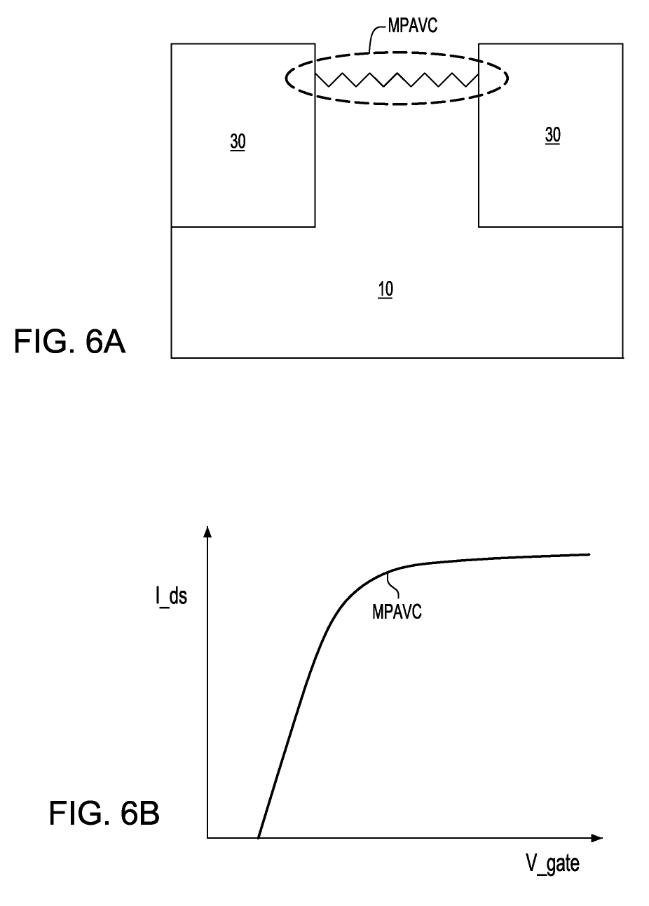

FIG. 6A shows a cross-section of a MOSFET with a multiple parallel adjoined V-shaped channels labeled “MPAVC” according to the present invention. The multiple parallel adjoined V-shaped channels are formed on a silicon substrate 10 and are surrounded by STI 30. The width of the individual facets is sub-lithographic and the distance between adjacent corners is therefore also sub-lithographic. For these sub-lithographically faceted surfaces, their narrow widths and close spacing result in lower off-current and higher on-current. As such, the threshold voltages of flat regions do not matter since the entire structure essentially consists only of the equivalent of surface corners in FIG. 5A. The electrical characteristics of the MOSFET built on the multiple parallel adjoined V-shaped channel is dominated by the large number of corners.

The resulting electrical characteristics of the MOSFET in FIG. 6A according to the present invention are shown in FIG. 6B. There is only one component of the transistor current since the flat portion “F” in FIG. 5A does not exist in the MOSFET according to the present invention. The threshold voltage of the MOSFET can be adjusted and tailored with threshold voltage adjustment implants. Therefore, the adverse I_on to I_off ratio that was present in the MOSFET built on a single V-shaped channel with lithographic dimensions is eliminated according to the present invention.

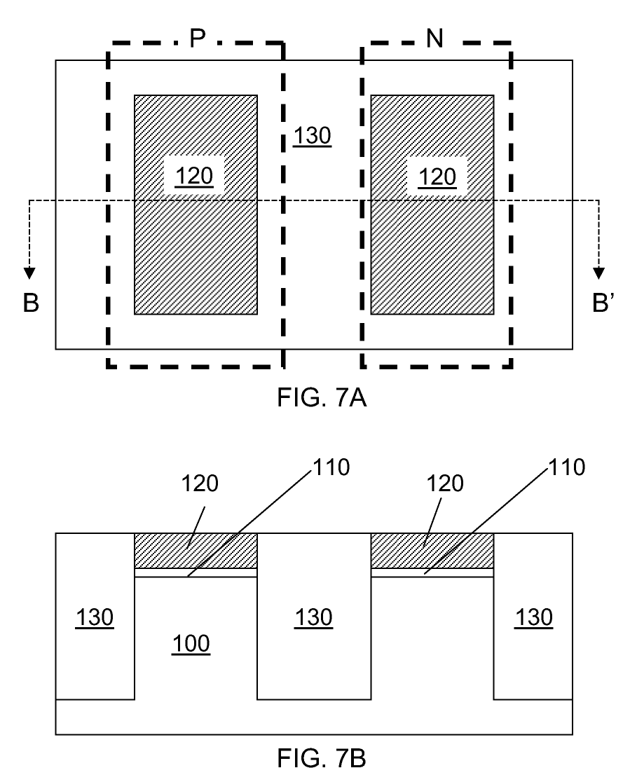

Proceeding with the description of the present invention, FIG. 7A-7B shows a (100) silicon substrate 100, patterned pad oxide 110, patterned pad nitride 120, and STI 130 surrounding a PFET area and an NFET area. IN FIG. 7A, the PFET area is the area not covered by the STI 130 and located within the dotted rectangle labeled P. The NFET area is the area not covered by the STI 130 and located within the dotted rectangle labeled N.

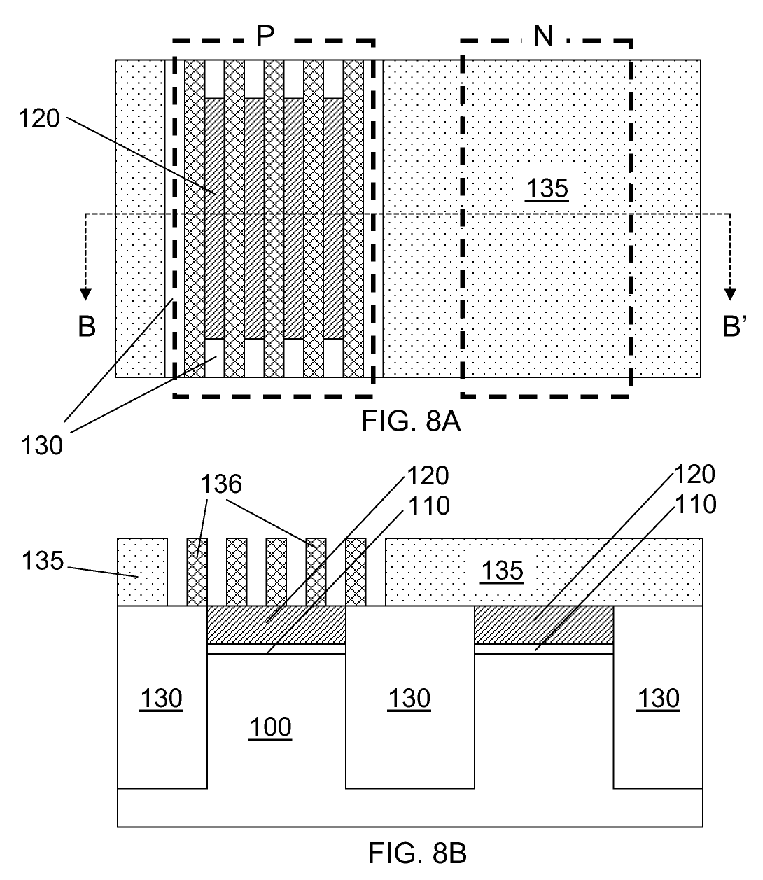

According to the first embodiment of the present invention, a first photoresist 135 is applied to the top surface of the silicon substrate patterned with STI 130. The first photoresist is patterned to create a space with parallel edges over the PFET area. The parallel edges of the first photoresist are preferably located outside the PFET area within the adjoining STI 130. Thereafter, a self-aligning self-assembling material is applied to the space over the PFET area and allowed to self-assemble and self-align to the surrounding pattern of the first resist 136. The self-aligned self-assembled resist 136 creates a pattern of multiple parallel lines as shown in FIG. 8A-8B within the space formed over the PFET area. Multiple parallel lines of the underlying pad nitride 120 are also exposed underneath the spaces between the pattern of multiple parallel lines formed by the self-aligned self-assembling material 136.

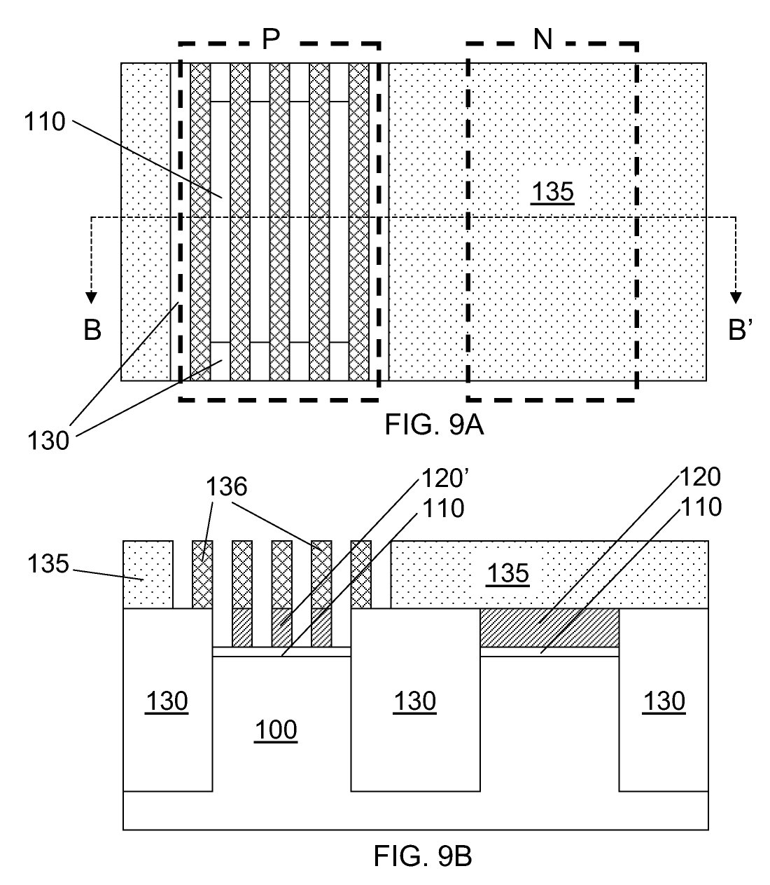

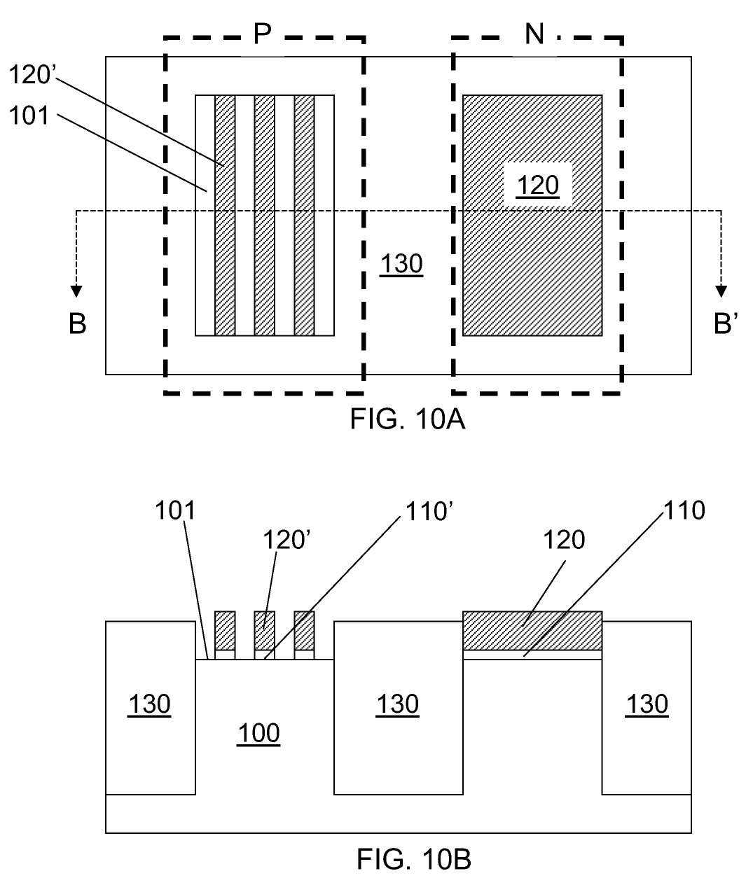

The exposed pattern, that is, the multiple parallel lines, over the pad nitride 120 is etched preferably by reactive ion etch (RIE) to form multiple parallel stacks of the pad nitride 120′ of sub-lithographic width as shown in FIGS. 9A-9B. Preferably, the RIE proceeds to the top of the pad oxide 110. After the formation of the pattern of multiple parallel lines of the pad nitride 120′, the first photoresist 135 and the self-aligned self-assembling material 136 are removed. Thereafter, the exposed portion of the pad oxide 110 between the multiple parallel lines of the pad nitride 120′ is etched to expose a first portion 101 of the silicon substrate 100 and multiple parallel stacks of the pad oxide 110′ and the pad nitride 120′ of sub-lithographic width as shown in FIGS. 10A-10B. At this stage, a stack of contiguous pad oxide 110 and contiguous pad nitride 120 exists over the NFET area while multiple parallel stacks of non-contiguous pad oxide 110′ and non-contiguous pad nitride 120′ exist over the PFET area. Alternatively, the pad oxide 110 may be etched to expose a first portion 101 of the silicon substrate 100 before removing the first photoresist 135 and the self-aligned self-assembling material 136.

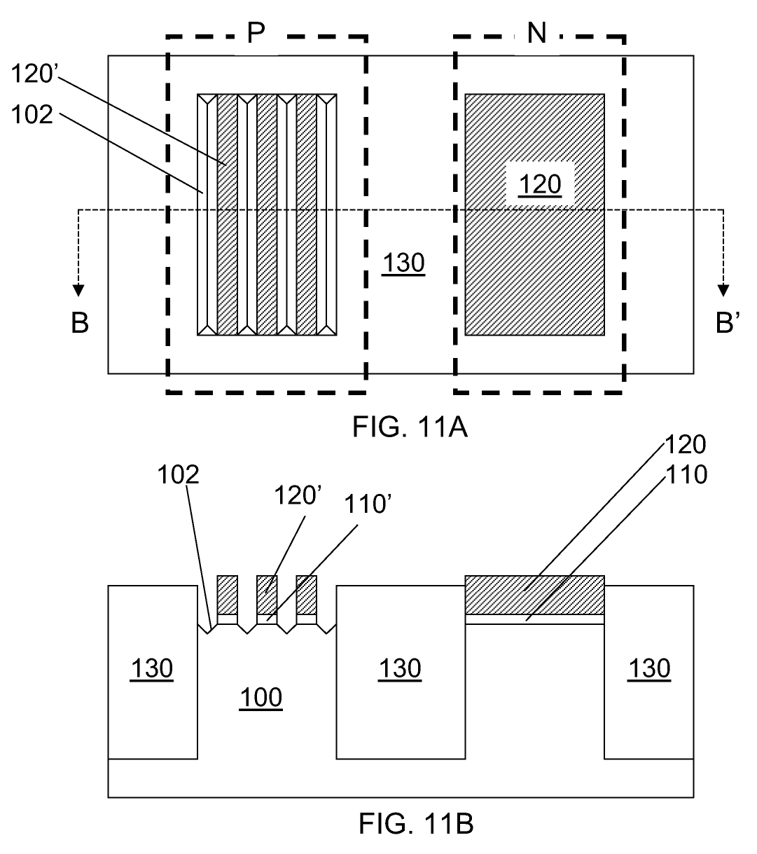

The first portion 101 of the silicon substrate 100 between the multiple parallel stacks of the pad oxide 110′ and the pad nitride 120′ of sub-lithographic width is then exposed to a first anisotropic etch with different etch rates along different crystallographic orientations of the silicon substrate 100. Crystallographic facets are etched from the first portion 101 of the silicon substrate to form a plurality of non-adjoining parallel V-shaped grooves 102 within the silicon substrate 100 as shown in FIGS. 11A-11B. Each of the plurality of non-adjoining parallel V-shaped grooves 102 has at least two crystallographic facets joined by a ridge in the middle of the V-shaped groove. Also, each of the “non-adjoining” parallel V-shaped grooves 102 is separated by a second portion 103 of the silicon surface between neighboring pairs of the V-shaped grooves 102. The second portion 103 of the silicon surface is at this point covered by the multiple parallel stacks of the pad oxide 110 and the contiguous pad nitride 120 of sub-lithographic widths.

The first anisotropic etch produces different etch rates along different crystallographic planes of the silicon crystal. According to the first embodiment of the present invention, the first anisotropic etch has a lower etch rate along at least one non-{100} plane than along the {100} planes. Preferably, the anisotropic etch rate is lowest along the {110} orientations so that {110} facets result in the multiple parallel V-shaped grooves in the PFET region on the (100) silicon substrate. The first anisotropic etch may be a reactive ion etch or a wet etch. An example of a wet etch chemistry that produces {110} facets comprises 23.4% KOH, 63.3% H2O, and 13.3% isopropyl alcohol at 80 C, which produces an etch rate of 60 nm/min on {110} silicon surfaces and 1,000 nm/min on {100} silicon surfaces.

While the first embodiment of the present invention utilizes a (100) silicon substrate and crystallographic facets formed in {110} orientations, the present invention can readily be generalized to utilize other substrate orientations or other crystallographic facet orientations. The type of surface orientation that the present invention enables is at an angle substantially greater than zero degree and substantially not orthogonal to the substrate orientations. For example, if the substrate orientation is (100) and the surface orientations after etching are {110} type planes, the angle between the substrate orientation and any of the surface orientation is 45 degrees. In general, the angle between two vectors in a cubic lattice can easily be calculated by the dot product of two vectors since the dot product is the length of the first vector times the length of the second vector times the cosine of the angle between the two vectors. The following tabulates angles between major crystallographic planes. Zero degree and 90 degree angles that are not intended to be obtained by the present invention are marked with N/A in table 1.

TABLE 1
Angles between substrate orientation and major crystallographic orientations
according to the present invention

| | Surface | Surface | Surface | Surface | Surface | Surface |
|---|---|---|---|---|---|---|
| | orientation | orientation | orientation | orientation | orientation | orientation |
| | {100} | {110} | {111} | {211} | {221} | {311} |
| Substrate | N/A | 45 degrees | ~54.73 degrees | ~35.26 or | ~48.18 or | ~25.24 or |
| orientation | | | | ~65.90 | ~70.53 | ~72.45 |
| (100) | | | | degrees | degrees | degrees |
| Substrate | 45 degrees | N/A | ~35.26 degrees | ~30.01, | ~19.47, 45 | ~31.48 or |
| orientation | | | | ~54.74 or | or ~76.36 | ~64.76 |
| (110) | | | | ~73.22 | degrees | degrees |
| | | | | degrees | | |
| Substrate | ~54.73 degrees | ~35.26 degrees | N/A | ~19.47 or | ~15.79, | ~29.49, |
| orientation | | | | ~61.87 | ~54.74 or | ~58.52 or |
| (111) | | | | degrees | ~78.90 | ~79.98 |
| | | | | | degrees | degrees |

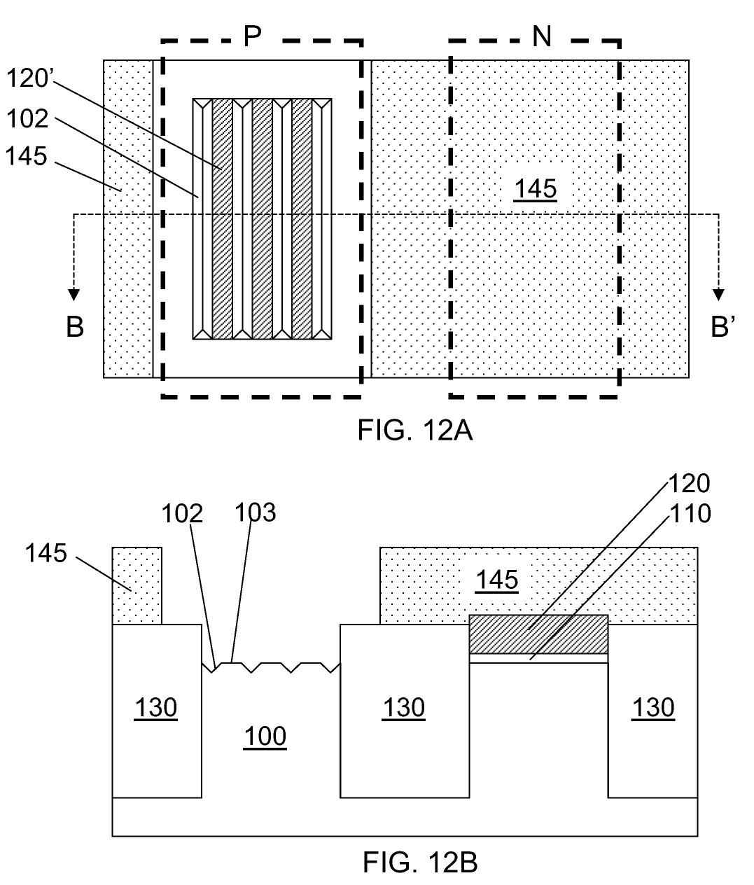

According to the present invention, a second photoresist 145 is preferably applied to the top surface of the silicon substrate 100 and patterned to cover the NFET area and expose the PFET area. The multiple parallel stacks of the pad oxide 110′ and the pad nitride 120′ of sub-lithographic widths are at this point removed to expose the second portion 102 of the silicon substrate 100. FIGS. 12A-12B show the structure of the MOSFETs at this stage. The second photoresist 145 is then removed.

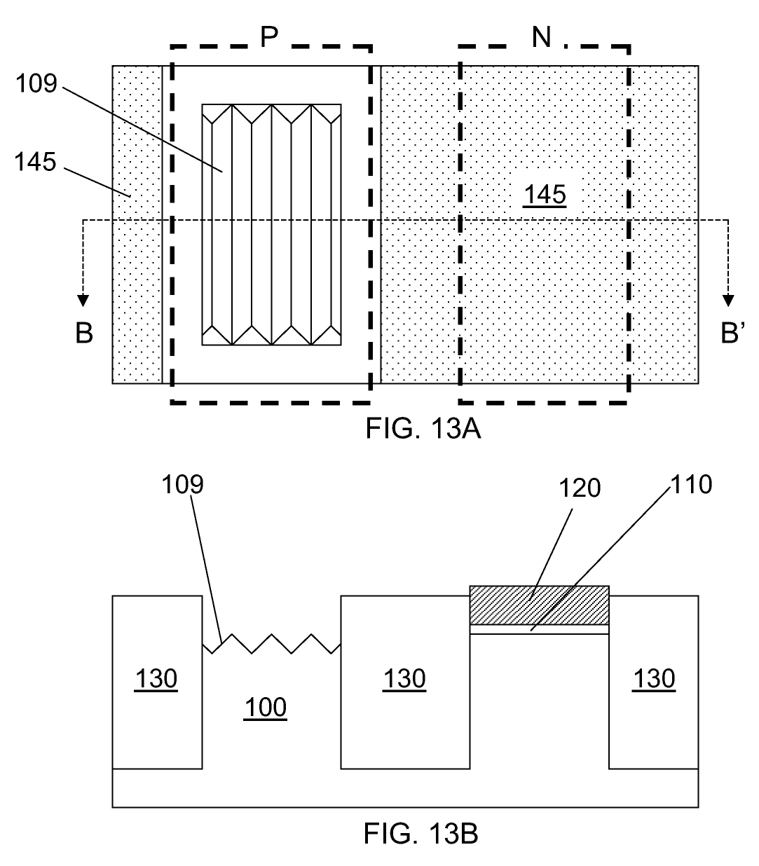

According to the first embodiment of the present invention, the multiple non-adjoining parallel V-shaped grooves 102 and the second portion 103 of the silicon surface between neighboring pairs of the V-shaped grooves 102 are exposed to a second anisotropic etch with different etch rates along different crystallographic orientations of said semiconductor substrate. Like the first anisotropic etch, the second anisotropic etch also has a higher etch rate on the {100} planes than on the facets of the pre-existing multiple parallel non-adjoining V-shaped grooves 102. Therefore, the silicon material is etched faster along the normal direction of the crystallographic facets of the multiple parallel non-adjoining V-shaped grooves 102 than along the normal direction of the second portion 103 of the silicon surface. The resulting structure is shown in FIGS. 13A-13B which shows multiple parallel “adjoining” V-shaped groves 109.

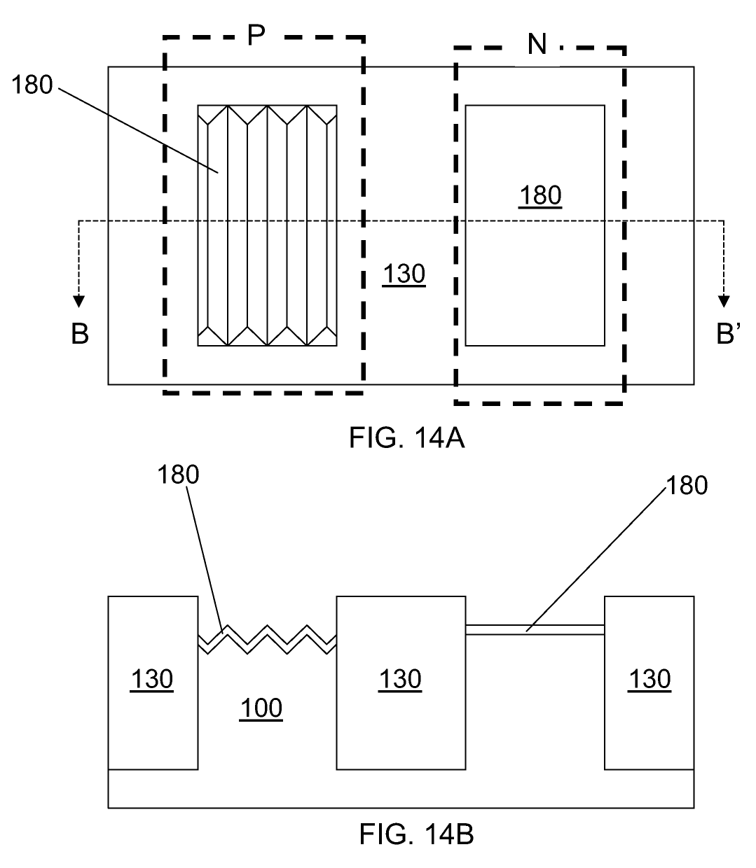

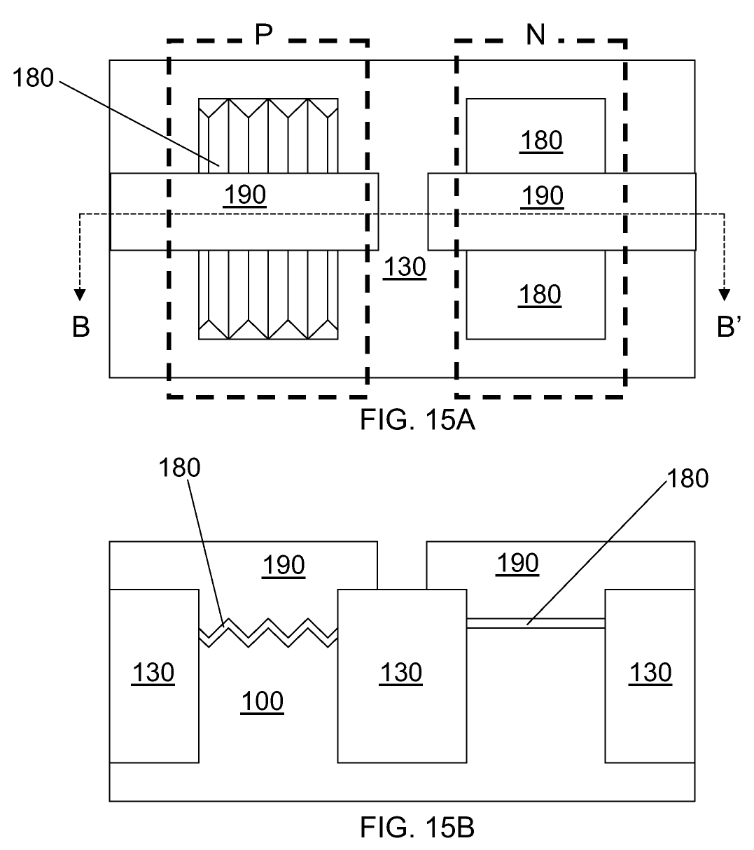

Thereafter, the contiguous pad nitride 120 and pad oxide 110 are removed from the NFET area. Gate dielectric 180 is formed both in the PFET area and in the NFET area as shown in FIGS. 14A-14B. Thereafter, gate conductor is deposited and patterned to form gate line 190 as shown in FIGS. 15A-15B.

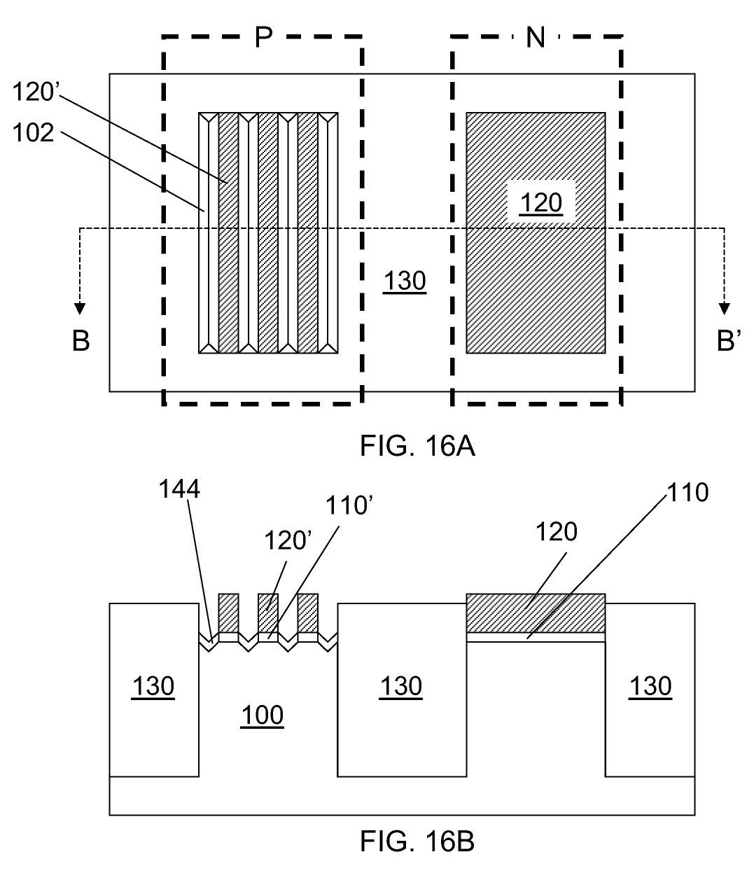

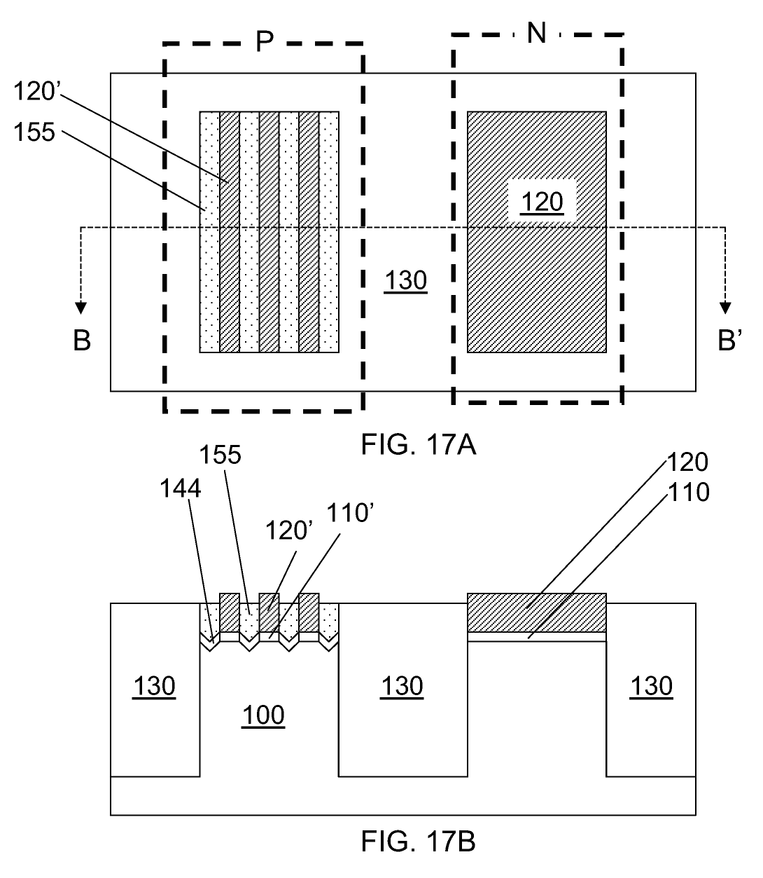

According the second embodiment of the present invention, the structures and methods according to the first embodiment of the present invention are utilized until the formation of the multiple parallel non-adjoining V-shaped facets 102 using the first anisotropic etch corresponding to FIGS. 11A-11B. Instead of applying a second photoresist 145 and removing the multiple parallel stacks of pad nitride 120′ and pad oxide 110′ as in the first embodiment, a sacrificial oxide 144 is formed either by deposition or growth over the multiple parallel non-adjoining V-shaped facets 102 as shown in FIGS. 16A-16B according to the second embodiment of the present invention.

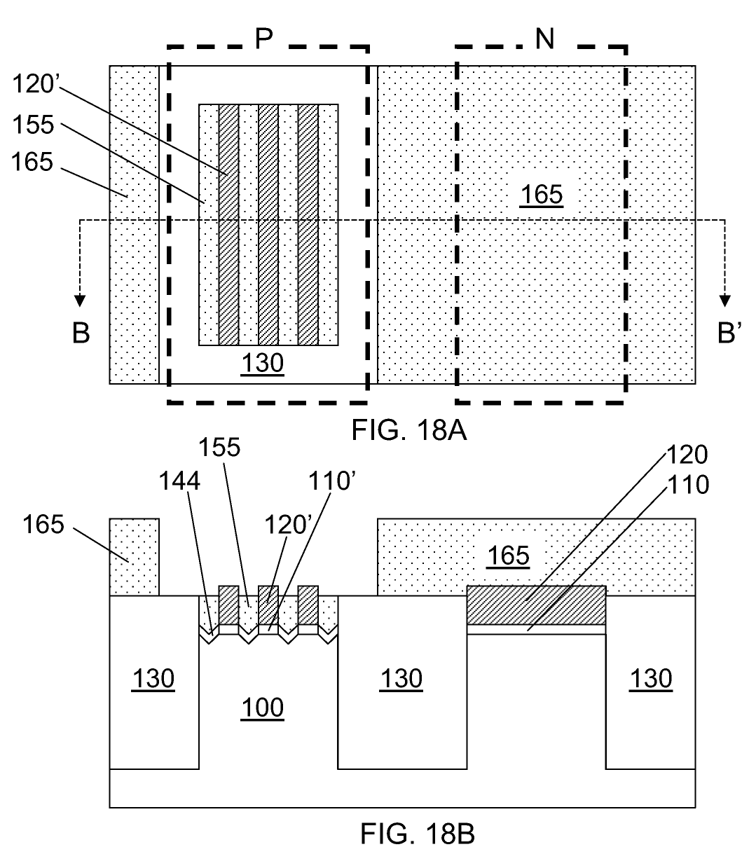

This is followed by filling of the volume above the sacrificial oxide 144 between the multiple stacks of the remaining pad oxide 110′ and the remaining pad nitride 120′ of sub-lithographic widths with a second photoresist 155. Preferably, the second photoresist 155 is applied to the top surface of the silicon substrate 100 and then recessed above the surfaces of the contiguous pad nitride 120 over the NFET area and the STI 130 such that the second photoresist 155 remains only between the stacks of pad nitride 120′ and pad oxide 110′ of sub-lithographic widths within the PFET area. Preferably, a third resist 165 is applied to the top surface of the silicon substrate 100 and patterned such that the NFET area of silicon substrate 100 is masked with a third photoresist to protect the pad oxide and pad nitride in the NFET area from the subsequent processing as shown in FIGS. 18A-18B.

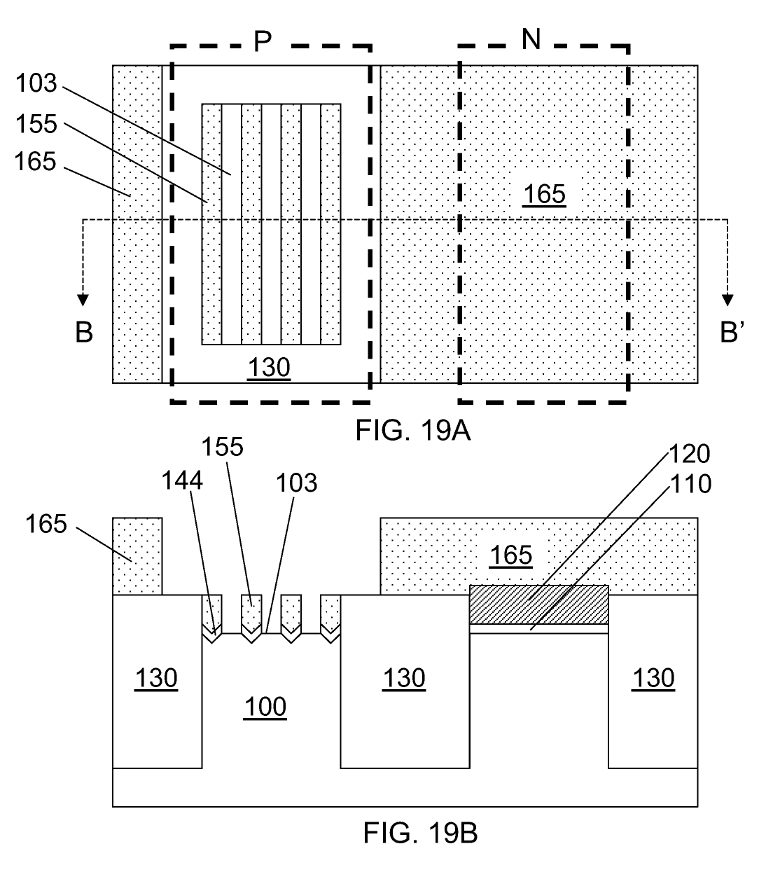

According to the second embodiment of the present invention, the multiple stacks of remaining pad oxide 110′ and pad nitride 120′ of sub-lithographic widths are then removed to expose a second portion 103 of the silicon surface preferably with a RIE process as shown in FIGS. 19A-19B. The second portion 103 is the flat portion of silicon surface between the edges of neighboring pairs of the multiple parallel non-adjoining V-shaped grooves 102.

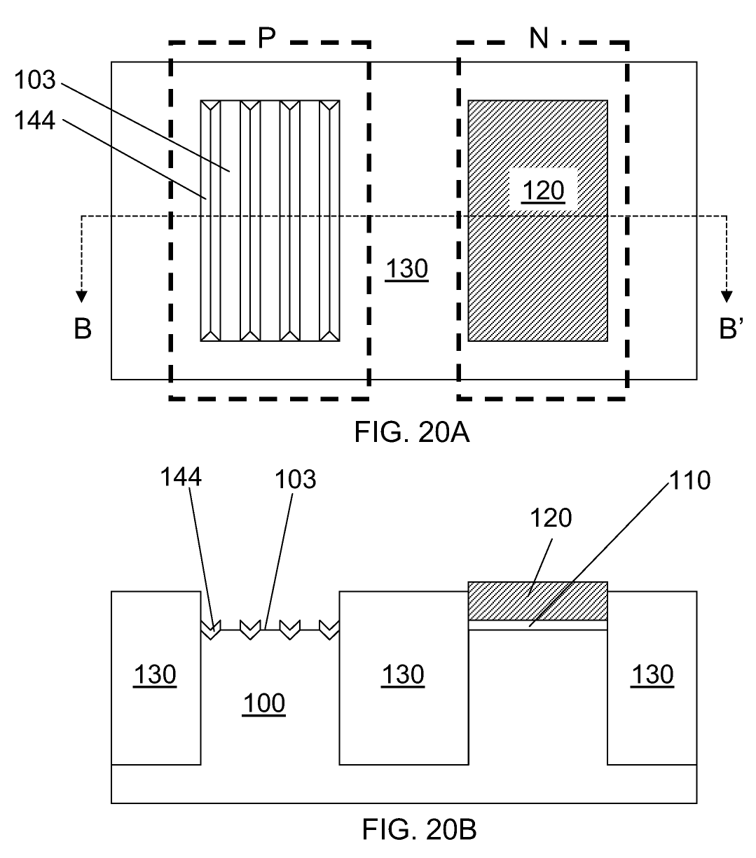

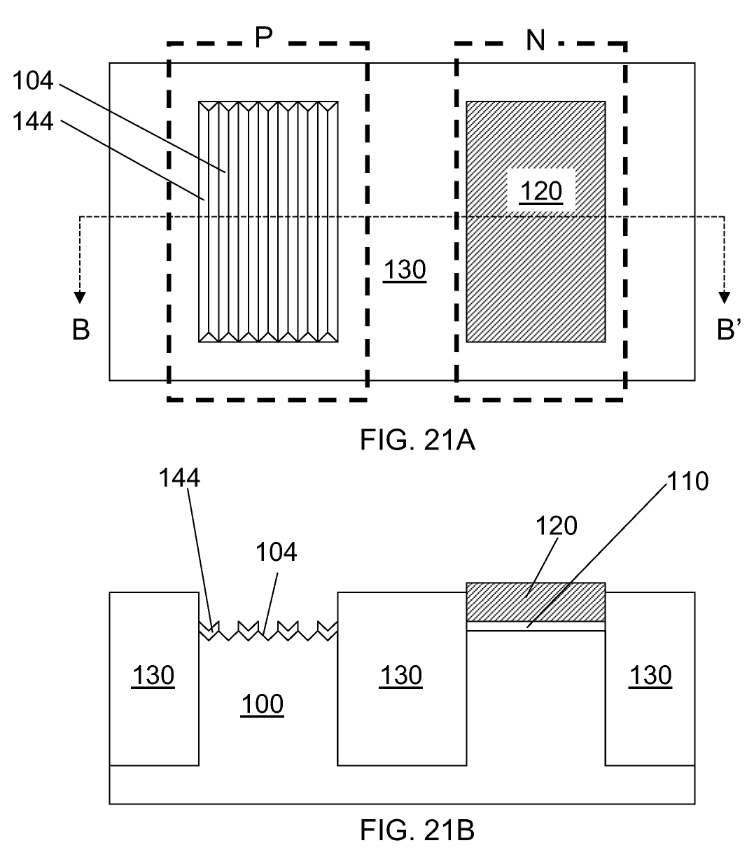

Preferably, the second photoresist 155 and the third resist 165 are also removed leaving only sacrificial oxide 144 over the non-adjoining parallel V-shaped grooves 102. The resulting structure has the sacrificial oxide 144 over the multiple parallel non-adjoining V-shaped grooves 102 separated by a second portion 103 between the edges of neighboring pairs of the multiple parallel non-adjoining V-shaped grooves 102 as shown in FIGS. 20A-20B.

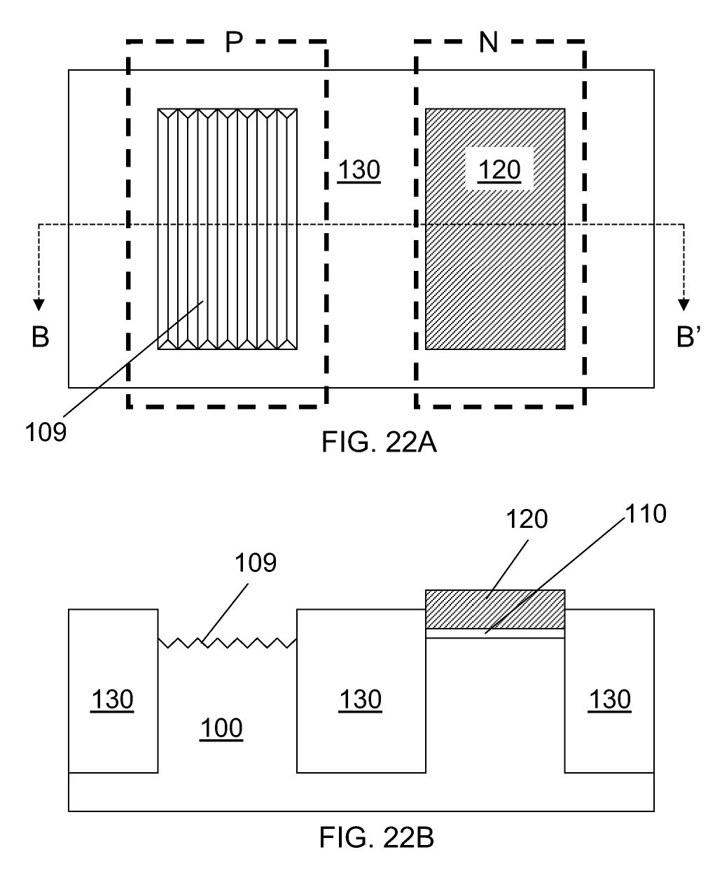

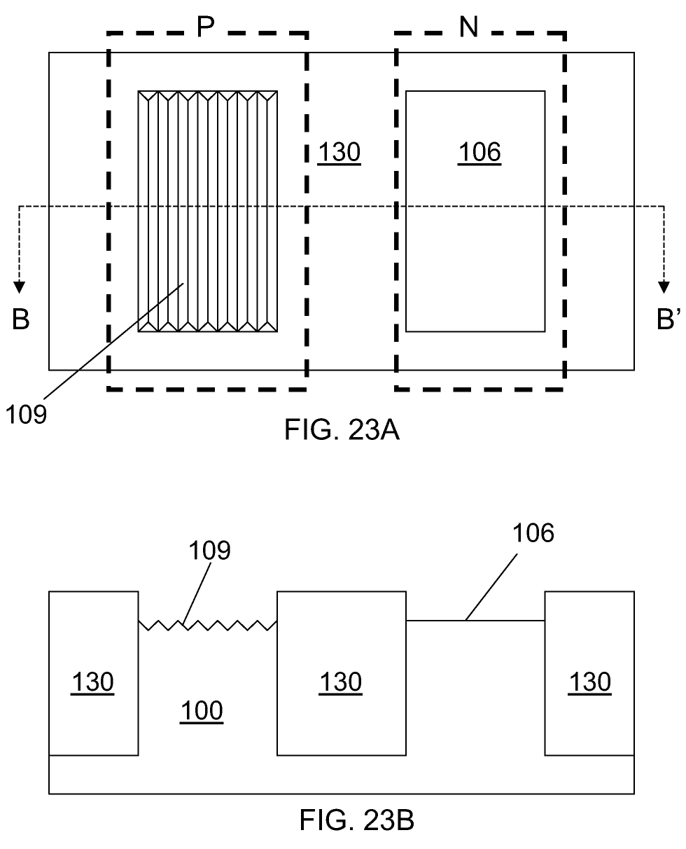

A second anisotropic etch is then performed to form a second set of multiple parallel V-shaped grooves between the previously non-adjoining parallel V-shaped grooves 102 as shown in FIGS. 21A-21B. While none of the previously non-adjoining V-shaped grooves 102 adjoin another one of the previously non-adjoining V-shaped grooves 102, the parallel edges of the newly formed multiple parallel V-shaped grooves 104 now adjoin the parallel edges of the previously non-adjoining parallel V-shaped grooves 102. Therefore, the previously non-adjoining parallel V-shaped grooves 102 and the newly formed V-grooves 104 formed between a pair of the non-adjoining parallel V-shaped grooves collectively form a new structure of multiple parallel adjoining V-shaped grooves 109 as shown in FIG. 22A-22B, wherein the same structure as in FIGS. 21A-21B is shown after removing the sacrificial oxide 144.

As in the first embodiment of the present invention, the second anisotropic etch has with different etch rates along different crystallographic orientations of said semiconductor substrate like the first anisotropic etch. The same limitations and variations on the processes for the anisotropic etch and on the choice of substrate orientation and crystallographic orientations apply to the second embodiment as to the first embodiment of the present invention.

According to the second embodiment of the present invention, however, the pitch of the adjoining parallel V-shaped grooves is equal to one half of the sub-lithographic pitch of the self-aligned self-assembling lithographic material. Almost twice as many parallel adjoining V-shaped channels are formed according to the second embodiment of the present invention as according to the first embodiment.

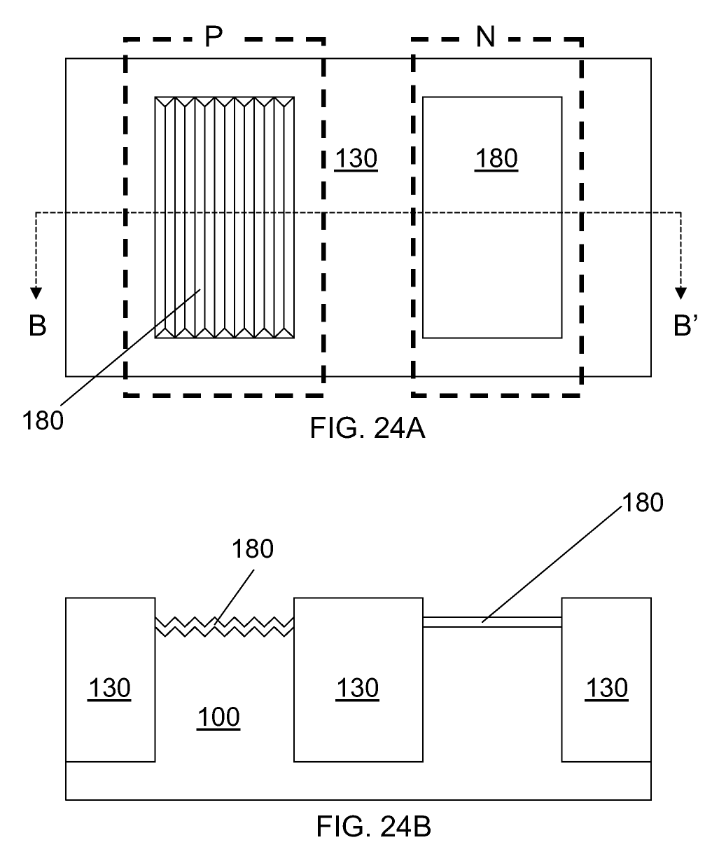

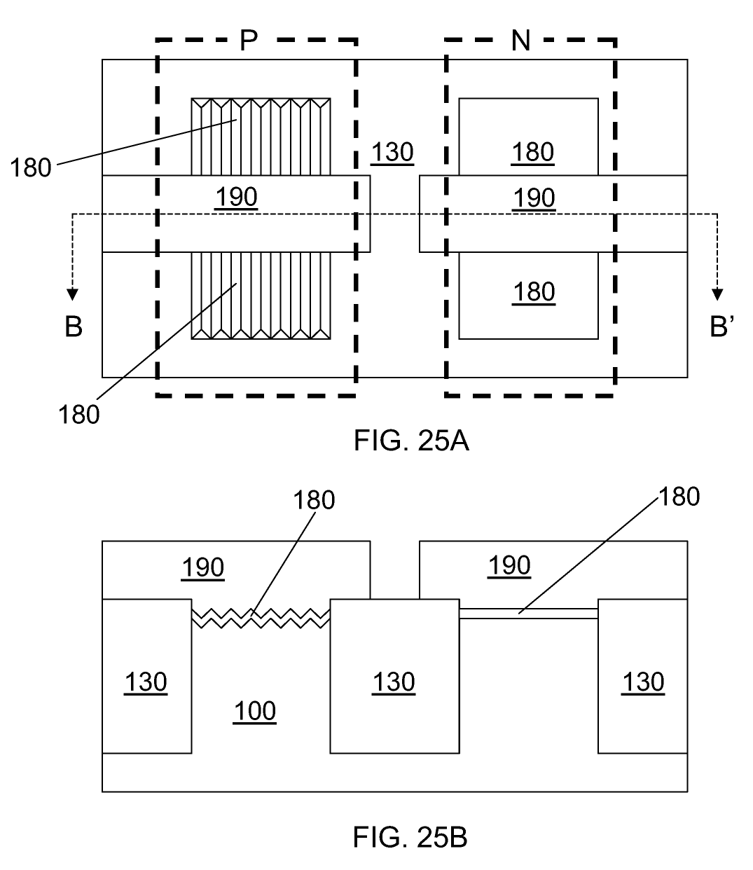

As in the first embodiment, the pad nitride 120′ and the pad oxide 110′ are removed as shown in FIGS. 24A-24B followed by a deposition and patterning of a gate conductor stack to form gate lines 190 as shown in FIGS. 25A-25B.

According to the both embodiments of the present invention, within each V-shaped groove, a ridge at which two crystallographic facets meet is at the bottom and near the middle of the V-shaped groove. The two crystallographic facets that adjoin the ridge within each V-shaped groove is shaped like a trapezoid with two parallel edges, wherein the longer parallel edge is one of the parallel outer edges of the V-shaped channel and the shorter parallel edges is the ride. The physical channel is formed out of portions of the two trapezoid facets that overlap the gate line 190. The current of the PFET flows along the pair of parallel edges, or the direction of the ridge in the middle of each V-shaped groove. Source and drain are formed on both sides of the gate line 190 to form a complete MOSFET.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A semiconductor structure comprising a plurality of parallel adjoining V-shaped grooves with crystallographic facets within a semiconductor substrate.

2. The semiconductor structure of claim 1, wherein each of said plurality of parallel adjoining V-shaped grooves with crystallographic facets has a width less than a lithographic minimum dimension.

3. The semiconductor of claim 1, wherein said semiconductor substrate is a silicon substrate.

4. The semiconductor structure of claim 3, wherein said single crystalline substrate has a (100) substrate orientation and at least four of said crystallographic facets have {110} orientations.

5. The semiconductor structure of claim 4, wherein said semiconductor structure is a p-channel metal oxide semiconductor field effect transistor (MOSFET).

6. The semiconductor structure of claim 3, wherein said single crystalline substrate has a (110) substrate orientation and at least four of said crystallographic facets have {100} orientations.

7. The semiconductor structure of claim 4, wherein said semiconductor structure is an n-channel metal oxide semiconductor field effect transistor (MOSFET).

8. The semiconductor structure of claim 3, wherein said at least four of said crystallographic facets are adjoined trapezoid facets and have orientations selected from the group consisting of {100} orientations, {110} orientations, {111} orientations, {211} orientations, {221} orientations, and {311} orientations.

9. The semiconductor structure of claim 1, wherein said semiconductor substrate is a silicon-on-insulator (SOI) substrate with at least one buried oxide (BOX) layer.

10. The semiconductor structure of claim 1, wherein said semiconductor substrate contains:
single crystalline silicon substrate; and
an epitaxially disposed material on said single crystalline silicon substrate that is selected from the group consisting of:
intrinsic silicon, intrinsic silicon germanium alloy, intrinsic silicon carbon alloy, intrinsic silicon germanium carbon alloy, P-doped silicon, P-doped silicon germanium alloy, P-doped silicon carbon alloy, P-doped silicon germanium carbon alloy, N-doped silicon, N-doped silicon germanium alloy, N-doped silicon carbon alloy, and N-doped silicon germanium carbon alloy.

11. The semiconductor structure of claim 1, wherein said plurality of parallel adjoining V-shaped grooves are aligned to shallow trench isolation (STI).

12. A method of fabricating a semiconductor structure, comprising:
providing a semiconductor substrate with a substrate orientation;
patterning a portion of said semiconductor with a self-aligned self-assembling lithographic material;
forming within said semiconductor substrate a plurality of non-adjoining parallel V-shaped grooves with crystallographic facets, wherein each of said plurality of non-adjoining parallel V-shaped grooves are separated by a flat portion of semiconductor surface between neighboring pairs of said V-shaped grooves; and
forming within said semiconductor substrate a plurality of adjoining parallel V-shaped grooves with crystallographic facets.

13. A method of fabricating a semiconductor structure of claim 11, further comprising, after patterning said portion of said semiconductor substrate with said self-aligned self-assembling lithographic material and before forming within said semiconductor substrate said plurality of non-adjoining parallel V-shaped grooves with crystallographic facets:
exposing a first portion of said semiconductor substrate to a first anisotropic etch with different etch rates along different crystallographic orientations of said semiconductor substrate.

14. A method of fabricating a semiconductor structure of claim 13, further comprising:
depositing a stack of a pad oxide layer and a nitride layer before patterning said portion of said semiconductor substrate with said self-aligned self-assembling lithographic material.

15. A method of fabricating a semiconductor structure of claim 14, further comprising, after patterning said portion of said semiconductor substrate with said self-aligned self-assembling lithographic material and before exposing said first portion of said semiconductor substrate to said first anisotropic etch:
etching a portion of said stack of said pad oxide layer and said nitride layer; and
forming multiple parallel stacks of said pad oxide and said pad nitride of sub-lithographic width.

16. A method of fabricating a semiconductor structure of claim 15, further comprising, after forming within a semiconductor substrate a plurality of non-adjoining parallel V-shaped grooves with crystallographic facets and before forming within said semiconductor substrate said plurality of adjoining parallel V-shaped grooves with crystallographic facets:
removing said parallel stacks of said pad oxide and said pad nitride of sub-lithographic width; and
exposing said a plurality of non-adjoining parallel V-shaped grooves and said flat portions of semiconductor surface between neighboring pairs of said V-shaped grooves to a second anisotropic etch with different etch rates along different crystallographic orientations of said semiconductor substrate.

17. A method of fabricating a semiconductor structure of claim 16, wherein said adjoining parallel V-shaped grooves have a pitch that equals the sub-lithographic pitch of said self-aligned self-assembling lithographic material.

18. A method of fabricating a semiconductor structure of claim 15, further comprising, after forming within a semiconductor substrate a plurality of non-adjoining parallel V-shaped grooves with crystallographic facets and before forming within said semiconductor substrate said plurality of adjoining parallel V-shaped grooves with crystallographic facets:
forming a sacrificial oxide on said plurality of non-adjoining parallel V-shaped grooves with crystallographic facets;
filling the volume above said sacrificial oxide with a second photoresist;
removing said parallel stacks of said pad oxide and said pad nitride of sub-lithographic width; and
exposing said flat portions of semiconductor surface between neighboring pairs of said V-shaped grooves to a second anisotropic etch with different etch rates along different crystallographic orientations of said semiconductor substrate.

19. A method of fabricating a semiconductor structure of claim 18, further comprising, after filling the volume above said sacrificial oxide with a first photoresist and before removing said parallel stacks of said pad oxide and said pad nitride of sub-lithographic width:
masking a portion of said semiconductor substrate with a third photoresist.

20. A method of fabricating a semiconductor structure of claim 19, wherein the pitch of said adjoining parallel V-shaped grooves is equal to one half of the sub-lithographic pitch of said self-aligned self-assembling lithographic material.
